(19) United States
(12) Patent Application Publication
(10) Pub. No.: US 2026/0155821 A1
(43) Pub. Date: Jun. 4, 2026

(54) Active Gate Control Method for Power Delivery of Semiconductor Power Devices

(71) Applicant: Nanjing Greenchip Semiconductor co. Ltd., Nanjing (CN)

(72) Inventor: Wen-An Tsou, Nanjing (CN)

(21) Appl. No.: 19/059,354

(22) Filed: Feb. 21, 2025

(30) Foreign Application Priority Data
Nov. 29, 2024 (CN) 202411737399.1

(51) Int. Cl. H03K 17/687; H02M 1/08; H02M 3/335

(52) U.S. Cl. CPC H03K 17/6871; H02M 1/08; H02M 3/33523

(57) ABSTRACT

The present invention discloses an active gate control method for power delivery of a semiconductor power device is disclosed, which includes providing a driving circuit to drive switching actions of the semiconductor power device, wherein the driving circuit is configured to perform following steps: detecting a threshold voltage of the semiconductor power device during a conduction period of said semiconductor power device; controlling gate-source voltage of the semiconductor power device to be higher than the threshold voltage and between the threshold voltage and a Miller voltage; and maintaining a voltage value of the gate-source voltage at the Miller voltage for a period of time; wherein the semiconductor power device is a GaN power transistor.

### TECHNICAL FIELD

The present invention relates to technical filed of power delivery (PD) of semiconductor power devices, in particular to an active gate control method for power delivery of semiconductor power devices.

### BACKGROUND

As well known in technical field of power electronic system, switching power supply technology has been widely used in the field of power circuits. In switching circuits, power transistors used as switching devices, such as MOSFET, IGBT, SiC or GaN, are widely used in various power electronic systems.

In power electronic systems, the performance of semiconductor power devices directly affects the power conversion efficiency of the entire system. In recent years, third-generation wide-bandgap semiconductor power devices represented by SiC and GaN have gradually replaced traditional Si-based semiconductor devices with their excellent switching performance.

When designing a switch-mode power supply, the main figures of merit (FOM) include cost, size, and efficiency. These three FOMs are coupled and require many factors to be considered. For example, increasing switching frequency can reduce the size and cost of magnetic components but increase losses of the magnetic components and switching losses of the power devices. Because GaN has low parasitic capacitance and no diode reverse recovery, GaN power devices have the potential to significantly reduce losses compared with MOSFETs and IGBTs, making them suitable for fast charging, i.e., power-delivery (PD).

However, gallium nitride (GaN) power devices cannot directly replace traditional silicon-based MOSFETs in power circuitry because the characteristics of GaN itself must be considered, such as gate-source voltage (VGS) limitations, low threshold voltage (Vₜₕ) and no body-diode. Therefore, traditional circuits for driving MOSFETs can no longer be effectively applied to drive GaN devices.

In order to solve this issue, it is necessary to provide a novel gate control method for GaN power devices applied in charging circuits.

### SUMMARY OF THE INVENTION

In order to improve the above deficiencies, according to one aspect of the present invention, an active gate control method for power delivery of a semiconductor power device is disclosed, which includes providing a driving circuit to drive switching actions of the semiconductor power device, wherein the driving circuit is configured to perform following steps: detecting a threshold voltage of the semiconductor power device during a conduction period of said semiconductor power device; controlling gate-source voltage of the semiconductor power device to be higher than the threshold voltage and between the threshold voltage and a Miller voltage; and maintaining a voltage value of the gate-source voltage at the Miller voltage for a period of time; wherein the semiconductor power device is a GaN power transistor. The period of time is ranged from 150 ns to 200 ns.

In one preferred embodiment, the active gate control method for power delivery of a semiconductor power device further includes increasing said gate-source voltage to an output stage voltage after said GaN power transistor being turned on. The driving circuit includes an active gate control module configured to electrically connect to the first transistor and the second transistor to respectively act as an upper drive transistor and a lower drive transistor, wherein gate of the GaN power transistor is driven by the upper drive transistor and the lower drive transistor. The upper drive transistor and the lower drive transistor are respectively driven by PWM control signals S1 and S2, wherein the upper drive transistor and the lower drive transistor cannot be turned on or turned off at the same time.

In one preferred embodiment, the upper drive transistor is a NMOS transistor and the lower drive transistor is a NMOS transistor, wherein source of said upper drive transistor is connected to drain of said lower drive transistor and is connected to gated of said GaN power transistor.

In one preferred embodiment, the threshold voltage is detected by a voltage detection circuit. The voltage detection circuit is disposed in interior of said active gate control module.

In one preferred embodiment, the step of maintaining said gate-source voltage at the Miller voltage period for the period of time is performed by the active gate control module.

In one preferred embodiment, the active gate control module is coupled to a reference voltage and a driving circuit control signal input.

According to another aspect of the present invention, an active gate control method for power delivery of a semiconductor power device is disclosed, which includes providing a driving circuit to drive switching actions of the semiconductor power device, wherein the driving circuit is configured to perform following steps: detecting a threshold voltage of the semiconductor power device during a conduction period of said semiconductor power device; controlling gate-source voltage of the semiconductor power device to be higher than the threshold voltage and between the threshold voltage and a Miller voltage; maintaining a voltage value of the gate-source voltage at the Miller voltage for a period of time; and increasing the gate-source voltage to an output stage voltage after said GaN power transistor being turned on; wherein the semiconductor power device is a GaN power transistor. The driving circuit includes an active gate control module configured to electrically connect to the first transistor and the second transistor to respectively act as an upper drive transistor and a lower drive transistor, wherein gate of the GaN power transistor is driven by the upper drive transistor and the lower drive transistor. The period of time is ranged from 150 ns to 200 ns.

In one preferred embodiment, the upper drive transistor and the lower drive transistor are respectively driven by PWM control signals S1 and S2, wherein the upper drive transistor and the lower drive transistor cannot be turned on or turned off at the same time.

In one preferred embodiment, the threshold voltage is detected by a voltage detection circuit. The voltage detection circuit is disposed in interior of said active gate control module.

In one preferred embodiment, the step of maintaining said gate-source voltage at the Miller voltage period for the period of time is performed by the active gate control module.

In one preferred embodiment, the active gate control module is coupled to a reference voltage and a driving circuit control signal input.

### BRIEF DESCRIPTION OF THE DRAWINGS

The components, characteristics and advantages of the present invention may be understood by the detailed descriptions of the preferred embodiments outlined in the specification and the drawings attached:

FIG. 1 shows the system circuit architecture of the GaN power transistor used for power-delivery (fast charging).

FIG. 2 shows a driving circuit for driving the GaN power transistor according to one embodiment of the present invention.

FIG. 3 shows a waveform diagram when the GaN power device is turned on according to one embodiment of the present invention.

FIG. 4 is a flowchart of the active gate control method for power delivery (fast charging) of the GaN power transistor according to one embodiment of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

The purpose of the present invention is to provide an active gate control method for fast charging of semiconductor power devices, such as GaN power transistors.

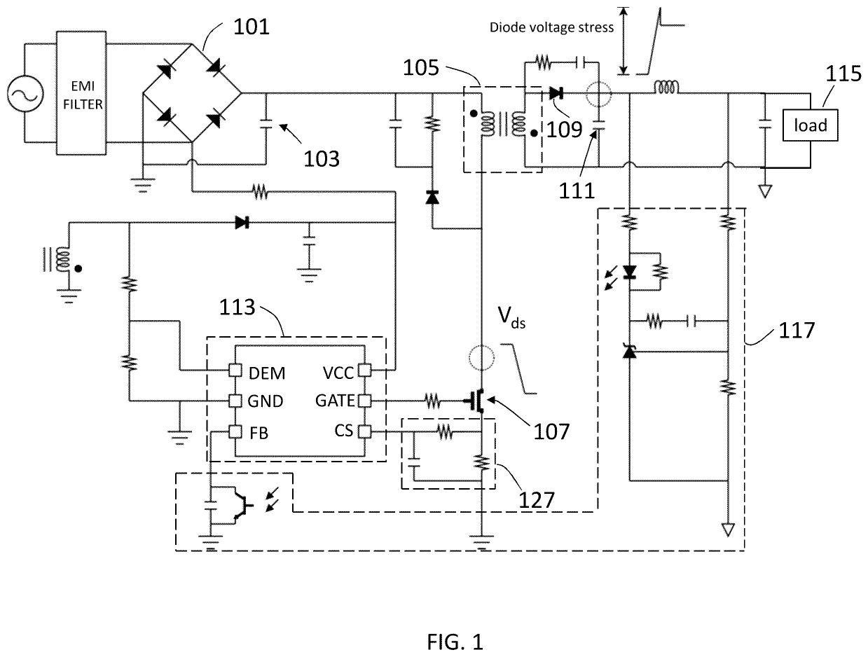

FIG. 1 shows the system circuit architecture of the GaN power transistor used for power-delivery (fast charging), which utilizes a flyback converter as an example. Referring to FIG. 1 for the circuit diagram of the most commonly used flyback converter. A household AC power inputs an input voltage through a bridge rectifier 101 and a capacitor 103 for rectifying and filtering the AC voltage into a DC voltage. The DC voltage is then transferred into the input of the transformer 105. The flyback converter has a power stage including a switching transistor 107, a diode 109, a transformer 105 and an output capacitor 111. By controlling the ON or OFF state of the switching transistor 107 via a PWM control circuit 113, a DC voltage can be output through the coupled rectifier circuit including a diode 109 and a capacitor 111 in the secondary side circuit. Due to the existence of air gap, the primary side winding Np of the transformer 105 has the triple functions of isolation, voltage transformation and inductance. Through the action of the switching transistor 107, the primary side winding Np of the transformer 105 receives the rectified DC power and stores the energy in the primary side winding Np when the switching transistor 107 is turned on. When the switching transistor 107 is turned off, the magnetization energy stored in the primary side winding Np of the transformer 105 is transferred to the secondary side winding Ns, and then through the charge holding function of capacitor 111 to obtain the DC voltage. The output circuit is disposed between the secondary winding Ns and the load 115 to output the DC voltage. The feedback circuit 117 receives the output of the flyback converter, and transmits the output changes of the flyback converter to the PWM control circuit 113 through the feedback circuit 117 to control the switching transistor 107.

Referring to FIG. 1, when the switching transistor 107 is replaced by a GaN power transistor, based on the characteristics of GaN itself, such as gate-source voltage V_{GS} limitation, low threshold voltage Vₜₕ, and no body-diode, the original design for silicon-based MOSFET gate control circuit is no longer suitable. Because the original gate drive circuit designed for power MOSFET is used to quickly turn on the power MOSFET, but due to the aforementioned characteristics of GaN power transistors, such as gate-source voltage V_{GS} limitation and low threshold voltage Vₜₕ, the same or a similar gate drive circuit design can generate a peak on the diode 109 of the secondary side due to the voltage stress caused by quickly turning on V_{GS}. This peak will cause the change of drain-source voltage ΔV_{DS} in the change of time Δt, i.e., ΔV_{DS}/Δt of the GaN power transistor 107, to form a steep slope, causing the GaN power transistor 107 to burn out.

To prevent the aforementioned issue from happening, the present invention proposes an active gate control method for power delivery (fast charging) of GaN power transistors.

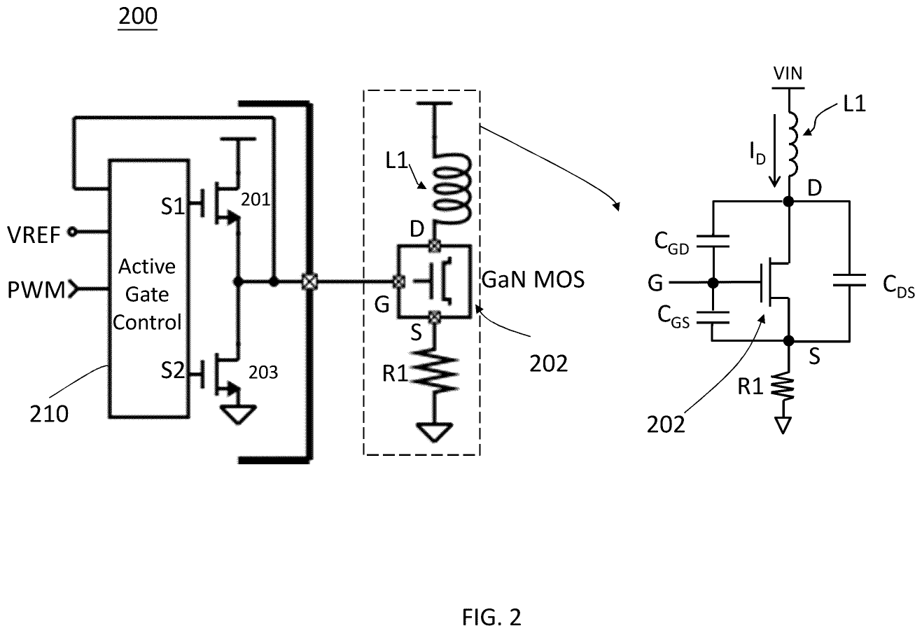

Please referring to FIG. 2, it depicts a driving circuit 200 for driving the GaN power transistor 202 according to one embodiment of the present invention, which includes an active gate control module 210 electrically connected to the first transistor 201 and the second transistor 203 both in switch form to act as an upper drive transistor and a lower drive transistor respectively, and the driving circuit 200 is used to drive the switching action of the main power switching transistor 202. The main power switching transistor 202 is a GaN power transistor, the gate G of the GaN power transistor is driven by the upper and lower drive transistors, which are part of the driving circuit 200. The upper and lower drive transistors are controlled through the control signals S1 and S2 respectively, the main power switching transistor 202 has a source terminal S connected to a resistor R then connected to ground and a drain terminal D connected to an external inductive load L1, the upper drive transistor (first transistor) 101 and the lower drive transistor (second transistor) 103 cannot be turned on or off at the same time. The gate terminal G of the main power switching transistor 202 is driven by the upper drive transistor and the lower drive transistor. At the moment while the upper drive transistor is turned on, the upper drive transistor charges the gate capacitance C_{G} (including the gate-source capacitance C_{GS} and the gate-drain capacitance C_{GD}) of the main power switching transistor 202 with its maximum current capability, so that the main power switching transistor 202 can be turned on.

In some embodiments, the first transistor 201 is a NMOS transistor and the second transistor 203 is a NMOS transistor. The upper drive transistor (the first transistor 201) has its source connected to the drain of the lower drive transistor (the second transistor 203).

In some embodiments, the active gate control module 210 is coupled to a reference voltage VREF and a driving circuit control signal input PWM.

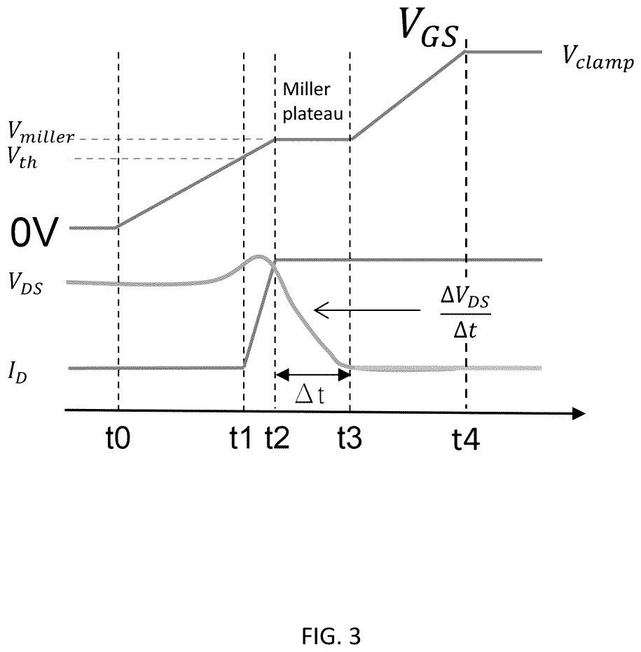

Please refer to FIG. 3, which shows a waveform diagram when the GaN power transistor 202 is turned on. Please refer to FIG. 2 together with FIG. 3. During the time period t0 to t1, the driving voltage begins to energize the GaN power transistor 202, this period is called the turn-on delay, because the drain-source voltage V_{DS} and drain current I_{D} of the device remain unchanged. The device remains in the off state. During the time period t1 to t2, the gate-source voltage V_{GS} rises from the threshold voltage Vₜₕ to the Miller platform voltage Vₘᵢₗₗₑᵣ. At time t1, the device begins to conduct, and the drain current I_{D} is proportional to the gate-source voltage V_{GS}. This is the linear operating regime of the device (constant flow regime). During the time period t2 to t3, which is the Miller plateau regime, all the gate current provided by the driving circuit 200 with active gate control function is transferred, thereby charging the C_{GD} capacitor so that a rapid voltage change (dropping to near zero) of the drain-source is achieved at the terminals, at which the drain current I_{D} of the device is limited by the external circuitry and therefore remains unchanged. During the time period t3 to t4, by applying a higher gate-source voltage V_{GS}, the on-current channel width of the GaN power device is fully increased, and V_{GS} rises from Vₘᵢₗₗₑᵣ to the final value V_{clamp}. This is achieved by charging the C_{GS} and C_{GD} capacitors. At this moment, the drain current I_{D} remains constant.

Referring to FIGS. 1-3, in order to avoid a spike (peak) caused by quickly turning on the V_{GS} of the GaN power device, which can cause the change of drain-source voltage ΔV_{DS} in the change of time Δt, i.e., ΔV_{DS}/Δt, of the GaN power transistor 107 to form a steep slope, enabling the GaN power transistor 107 to burn out. The present invention discloses an active gate control method for power delivery (fast charging) of GaN power transistor 202. The method mainly relies on the driving circuit 200, including the active gate control module 210, the upper drive transistor and the lower drive transistor electrically connected thereto, which is used to actively control the switching of the GaN power transistor 202 to achieve the purpose of fast charging (power delivery).

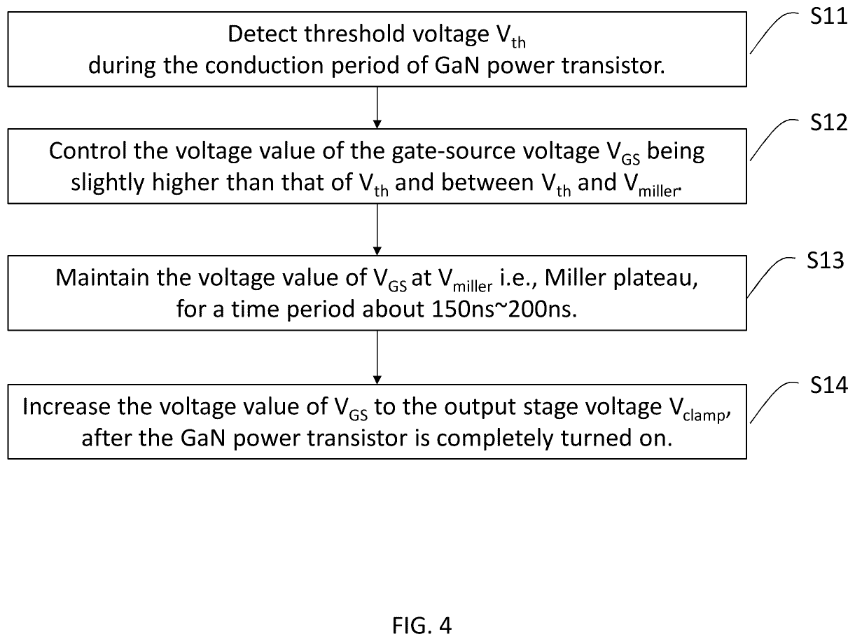

FIG. 4 is a flowchart of the active gate control method for power delivery (fast charging) of the GaN power transistor according to one embodiment of the present invention. The control method includes utilizing the driving circuit 200 to perform the following steps: firstly, in step S11, the driving circuit 200 is used to detect the threshold voltage Vₜₕ during the conduction period of the GaN power transistor 202; in step S12, the driving circuit 200 is used to control the voltage value of V_{GS} in a range that is slightly higher than that of Vₜₕ, and Vₜₕ<V_{GS}<Vₘᵢₗₗₑᵣ; in step S13, the time period Δt to maintain the voltage value of V_{GS} at Vₘᵢₗₗₑᵣ (i.e., Miller plateau) is approximately 150 ns˜200 ns; in step S14, after the GaN power transistor 202 is completely turned on, the voltage value of V_{GS} is increased to the output stage voltage V_{clamp}.

In some embodiments, the threshold voltage Vₜₕ in step S11 is detected through a voltage detection circuit, and the voltage detection circuit is disposed inside the active gate control module 210.

In some embodiments, step S13 is performed by the active gate control module 210 to maintain the voltage value of the gate-source voltage at the Miller voltage for a predetermined time.

According to the aforementioned method, the present invention can reduce the voltage stress of the diode on the secondary side of the flyback converter by soft-driving the Miller capacitor of the GaN power transistor. Therefore, the risk of peaks caused by voltage stress can effectively suppressed and the GaN power transistors can be protected.

While various embodiments of the present invention have been described above, it should be understood that they have been presented by a way of example and not limitation. Numerous modifications and variations within the scope of the invention are possible. The present invention should only be defined in accordance with the following claims.

What is claimed is:

1. An active gate control method for power delivery of a semiconductor power device, comprising:
providing a driving circuit to drive switching actions of said semiconductor power device, wherein said driving circuit is configured to perform following steps:
detecting a threshold voltage of said semiconductor power device during a conduction period of said semiconductor power device;
controlling a gate-source voltage of said semiconductor power device to be higher than said threshold voltage and between said threshold voltage and a Miller voltage; and
maintaining a voltage value of said gate-source voltage at said Miller voltage for a period of time;
wherein said semiconductor power device is a GaN power transistor.

2. The method of claim 1, further including increasing said gate-source voltage to an output stage voltage after said GaN power transistor being turned on.

3. The method of claim 1, wherein said period of time is ranged from 150 ns to 200 ns.

4. The method of claim 1, wherein said driving circuit includes:
an active gate control module configured to electrically connect to a first transistor and a second transistor to respectively act as an upper drive transistor and a lower drive transistor;
wherein gate of said GaN power transistor is driven by said upper drive transistor and said lower drive transistor.

5. The method of claim 4, wherein said upper drive transistor and said lower drive transistor are respectively driven by PWM control signals S1 and S2; wherein said upper drive transistor and said lower drive transistor cannot be turned on or turned off at the same time.

6. The method of claim 5, wherein said upper drive transistor is a NMOS transistor and said lower drive transistor is a NMOS transistor; wherein source of said upper drive transistor is connected to drain of said lower drive transistor and is connected to gate of said GaN power transistor.

7. The method of claim 6, wherein said threshold voltage is detected by a voltage detection circuit.

8. The method claim 7, wherein said voltage detection circuit is disposed in interior of said active gate control module.

9. The method of claim 4, wherein said step of maintaining said gate-source voltage at said Miller voltage period for said period of time is performed by said active gate control module.

10. The method of claim 9, wherein active gate control module is coupled to a reference voltage and a driving circuit control signal input.

11. An active gate control method for power delivery of a semiconductor power device, comprising:
providing a driving circuit to drive switching actions of said semiconductor power device, wherein said driving circuit is configured to perform following steps:
detecting a threshold voltage of said semiconductor power device during a conduction period of said semiconductor power device;
controlling a gate-source voltage of said semiconductor power device to be higher than said threshold voltage and between said threshold voltage and a Miller voltage;
maintaining a voltage value of said gate-source voltage at said Miller voltage for a period of time;
increasing said gate-source voltage to an output stage voltage after said GaN power transistor being turned on;
wherein said semiconductor power device is a GaN power transistor; and
wherein said driving circuit includes an active gate control module configured to electrically connect to a first transistor and a second transistor to respectively act as an upper drive transistor and a lower drive transistor; wherein said GaN power transistor is driven by said upper drive transistor and said lower drive transistor.

12. The method of claim 11, wherein said period of time is ranged from 150 ns to 200 ns.

13. The method of claim 11, wherein said upper drive transistor and said lower drive transistor are respectively driven by PWM control signals S1 and S2.

14. The method of claim 13, wherein said upper drive transistor and said lower drive transistor cannot be turned on or turned off at the same time.

15. The method of claim 14, wherein said upper drive transistor is a NMOS transistor and said lower drive transistor is a NMOS transistor.

16. The method of claim 15, wherein source of said upper drive transistor is connected to drain of said lower drive transistor and is connected to gate of said GaN power transistor.

17. The method of claim 16, wherein said threshold voltage is detected by a voltage detection circuit.

18. The method claim 16, wherein said voltage detection circuit is disposed in interior of said active gate control module.

19. The method of claim 11, wherein said step of maintaining said gate-source voltage at said Miller voltage period for said period of time is performed by said active gate control module.

20. The method of claim 18, wherein active gate control module is coupled to a reference voltage and a driving circuit control signal input.
